(19) United States
(12) Patent Application Publication
(10) Pub. No.: US 2003/0016487 A1
(43) Pub. Date: Jan. 23, 2003

(54) Method and apparatus of interface conversion for handheld device

(75) Inventors: Lu Tung-Chieh, Taipei Hsien (TW); Yen Shih-Ming, Taipei Hsien (TW); Chen Li-Hsiang, Taipei Hsien (TW)

Correspondence Address: BACON & THOMAS, PLLC, 625 SLATERS LANE, FOURTH FLOOR, ALEXANDRIA, VA, 22314

(73) Assignee: Acer Inc., Taipei Hsien (CN)

(21) Appl. No.: 10/022,444

(22) Filed: Dec. 20, 2001

(30) Foreign Application Priority Data
Jul. 6, 2001 (TW) 090116627

(51) Int. Cl. H05K 5/00

(52) U.S. Cl. 361/679

(57) ABSTRACT

The invention relates to an information handling system comprising a handheld device operable independently and having a first connector for external connection, wherein the handheld device functions in accordance with a first protocol and a second protocol; a first appendant device for the handheld device having a second connector for connecting to the first connector, wherein the first appendant device cooperates with the handheld device according to the first protocol inasmuch as the second connector is connected to the first connector; and a second appendant device for the handheld device having a third connector for connecting to the first connector, wherein the second appendant device cooperates with the handheld device according to the second protocol inasmuch as the third connector is connected to the first connector; wherein the first connector has connector pins whose number is less than the number specified in the first protocol for successful signal transmission between the handheld device and the first appendant device.

### REFERENCE TO RELATED APPLICATIONS

The present application claims priority to Taiwan application NO.090116627 entitled “Apparatus and method of expansion interface converter for handheld device” filed on July 7, 2001.

### BACKGROUND OF THE INVENTION

1. Field of the Invention

The present invention relates to method and apparatus for obtaining flexibility in using an electronic device having an expansion interface that allows expansion modules with additional functionalities to be incorporated. More particularly, it relates to method and apparatus for converting signals and switching between interfaces of a handheld electronic device for correct connection to expansion modules.

2. Description of the Related Art

Personal digital assistants, or PDAs, have become popular computer products in recent years. They are designed to be light-weighted, of small size that fits into the hands of the user, and can be conveniently put into pockets, which makes them highly portable as compared to heavy and sometimes cumbersome notebooks. The first PDA only allows users to edit and store messages and to perform simple word processing functions. Through the years the technology for PDAs has improved greatly and most of the important functions found in desktop or laptop computers have counterparts on PDAs, though specially adapted to conform to small memory and display.

A common feature of PDA is that it can transfer data with other computers through a mediating device called cradle. A typical cradle utilizes RS-232 as the transmission standard to allow signal transfer between the PDA and, say, a desktop computer. The cradle can also serve as a battery charger for the PDA.

Some PDAs also come with a jacket into which they can slide. The jacket has a PCMCIA or COMPACT FLASH slot that can receive expansion cards or functional modules so that additional functions or memory can be incorporated into the PDAs.

For the reason that RS-232 protocol used in a cradle, which is serial, is different from PCMCIA or COMPACT FLASH protocol used in a jacket, which is parallel, a PDA that can connect to the cradle and the jacket has to resort to two separate interfaces for correct connection, one serial and the other parallel, respectively. That is, there exist on the PDA at least two interfaces, one being RS-232 with 9 pins and the other being, say, PCMCIA with 68 pins, which results in a total number of connector pins up to eighty, and even more if still other interfaces are provided on the PDA. To accommodate these connector pins leads to occupation of excess space within the PDA and is in conflict with the requirement of compactness for handheld devices. Furthermore, exposing connector pins on the housing makes the PDA lose its appealing look to customers. It is needed therefore to reduce the total number of pins of a PDA so as to make it more compact and more appealing to the eye.

### SUMMARY OF THE INVENTION

In order to circumvent the shortcomings of the prior art outlined above, the present invention reduces the number of pins required of the PDA connector for connecting to a jacket by employing a parallel-serial conversion. According to one embodiment of the present invention, parallel signals of the PDA are bidirectionally converted into serial signals that can be transmitted through a compact connector interface to the jacket. Similarly, parallel signals of the jacket are bidirectionally converted into serial signals that can be transmitted though a compact connector interface to the PDA. When the PDA and the jacket are connected, straightforward parallel transmission over the PDA-jacket interface is replaced by first converting parallel signals into serial signals that are then transmitted over the compact connector interface and finally recovering the parallel signals from the serial signals transmitted. The reduction in pin number on the compact connector interface is proportional to the parallel-serial conversion ratio.

In another embodiment of the present invention, the inventive PDA is capable of connecting to a cradle using the same compact connector interface for connecting to the jacket. This is made possible by incorporating into the PDA a switch circuit that switchably connects either the serial signals for the cradle or the parallel signals for the jacket to the compact connector interface. A monitor means is also incorporated into the PDA that monitors the status of the compact connector interface for transmitting correct signals to the connected device accordingly.

Accordingly, the object of the present invention is to provide a method and apparatus for reducing the number of pins and the size of the connector interface between a PDA and its jacket.

Another object of the present invention is to provide a method and apparatus by which a PDA is able to connect to and communicate with its jacket and its cradle using a connector.

Still another object of the present invention is to provide a method and apparatus allowing a handheld device to connect to and communicate with two supplement devices using different transmission standards, one parallel and the other serial, through a compact connector.

### BRIEF DESCRIPTION OF THE DRAWINGS

The following detailed description, which is given by way of example, and not intended to limit the invention to the embodiments described herein, can best be understood in conjunction with the accompanying drawings, in which:

FIG. 1 illustrates the inventive PDA that can connect to an expansion module through a jacket.

FIG. 2 illustrates the different sizes of the interface on PDA, wherein FIG. 2a illustrates the large size of the interface of the prior art PDA, and FIG. 2b illustrates the reduced size of the interface of the inventive PDA.

FIG. 3 illustrates one embodiment of the present invention wherein the parallel interface between a PDA and its mating jacket is converted into a serial interface.

FIG. 4 illustrates in accordance with the present invention the conversion between parallel signals and serial signals, wherein FIG. 4a illustrates the serial-to-serial conversion and FIG. 4b illustrates the serial-to-parallel conversion.

FIG. 5 illustrates the inventive PDA capable of communicating with a desktop computer through a docking cradle.

FIG. 6 illustrates one embodiment of the present invention wherein the serial interface that replaces the parallel interface between a PDA and its mating jacket is made switchable for transmitting RS-232 signals between the PDA and its cradle.

### DETAILED DESCRIPTION OF THE INVENTION

With reference to the accompanying drawings the novelty and inventiveness of the present invention are described below. Though the following description pertains to PDA device and relating docking cradle and jacket, it is understood that the present invention can be applied to computer systems not under these names.

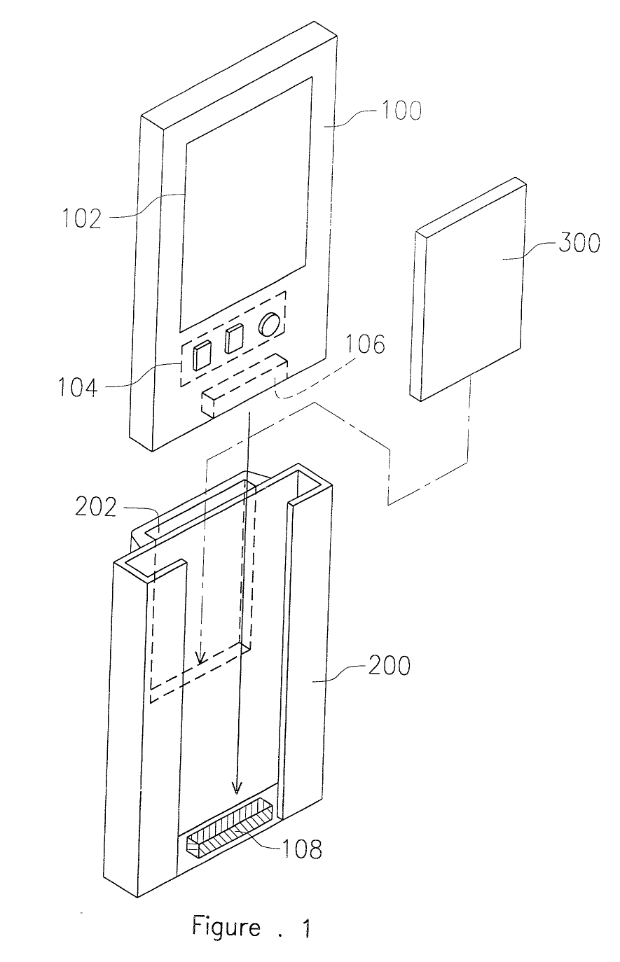

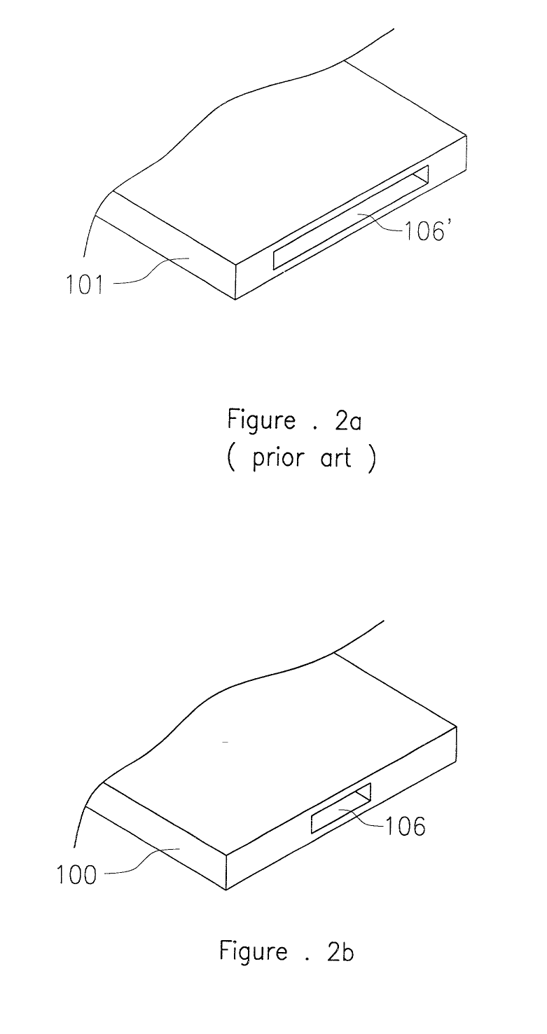

FIG. 1 illustrates the inventive PDA that can connect to an expansion module through a jacket. PDA 100 includes function keys 104 for performing certain operations when depressed, and a display 102 for showing messages and data to the user. As a common feature, the display 102 is usually covered with a touch-sensitive screen and can receive user input by touching the screen with either fingertip or stylus. This allows easy control and reduces the number of function keys to a minimum. Connector 106 is provided on the lower end of the PDA 100 and is used to connect to mating connector 108 of jacket 200. The jacket 200 has such a shape that when the PDA 100 has been slid in, it covers substantially all the PDA 100 except the display 102 and function keys 104. An expansion slot 202 is provided on a side of the jacket 200 for receiving expansion card 300. Through the jacket 200, the PDA 100 is able to transfer data with the expansion card 300 and thereby additional functions can be performed cooperatively. For example, the expansion card 300 can be a radio receiver module that, when slotted into the jacket 200 connected to the PDA 100, turns the PDA 100 into a radio receiver. Or it can be a flash memory card that provides more memory space to the PDA 100. The functions that the expansion card 300 can offer are various.

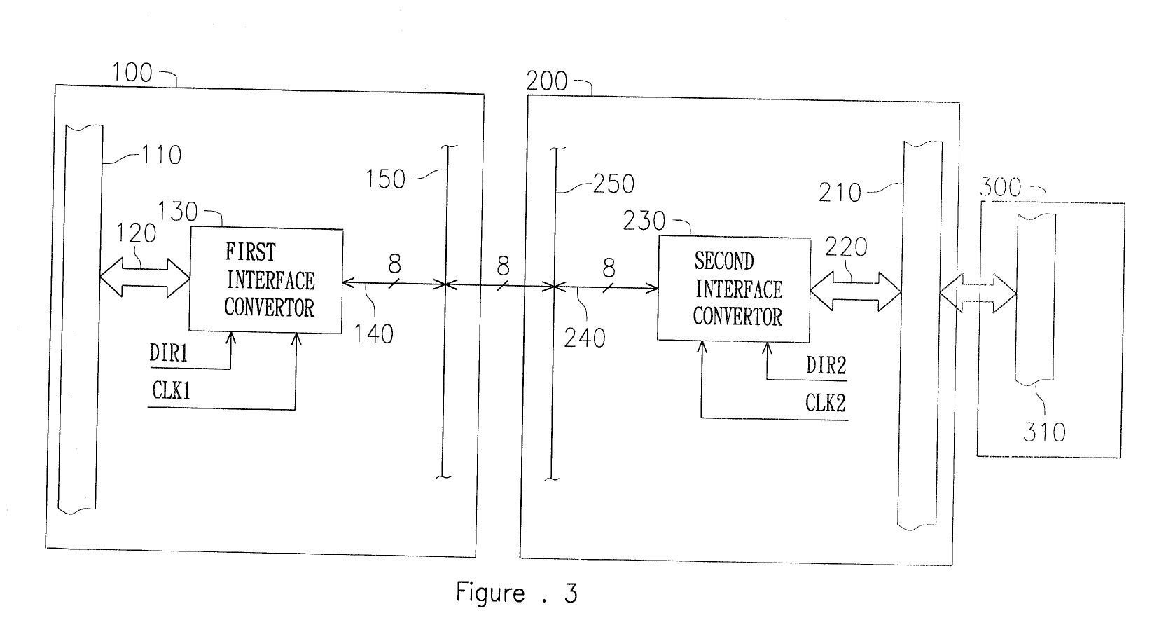

In the prior art, for an expansion card following either PCMCIA or COMPACT FLASH standard, the connector of a PDA and the corresponding connector of its jacket both have 68 pins or 50 pins for connection, respectively. In the present embodiment, the number of pins needed for the connector 106, and connector 108, is reduced by converting parallel signals of either PCMCIA or COMPACT FLASH format into serial signals. Because serial signals requires less connector pins for representing same data bytes than parallel signals, the size of the connector 106 and 108 can be compacted. FIG. 2 illustrates the different sizes of the interface on PDA for comparison, wherein FIG. 2a illustrates the large size of the connector 106′ of a typical PDA 101, and FIG. 2b illustrates the reduced size of the connector 106 of the inventive PDA 100. As the connector 106 is compacted, space is spared for other use inside the inventive PDA 100. The compactness is advantageous in making the inventive PDA 100 more attractive to users.

FIG. 3 is a schematic diagram of the inventive PDA of FIG. 1 for illustrating how parallel signal transmission between the PDA 100 and its mating jacket 200 are converted into serial signal transmission in order to reduce the number connector pins. In this diagram, a set of parallel signals is represented by a solid arrow headed symbol, indicating that the number of pins is of a great amount, and a set of serial signals is represented by a linear arrow headed symbol, indicating that the number of pins is of a small amount. The symbols representing either parallel or serial signals are made two-way arrow headed to reflect that the transmission is bi-directional. For simplicity, only interface components relating to the present invention are shown in this diagram.

The PDA 100, the jacket 200, and the expansion card 300 have parallel interface 110, 210, and 310, respectively, for parallel transmission. The interface 110 in this diagram signifies a part of the circuitry inside PDA 100 on which functions such as editing and browsing are performed and parallel signals 120 are generated and transferred. In the prior art, it is directly connected to a parallel connector for output. For parallel transmission, the connector would require too many pins the disadvantages of which are what the present invention sets out to overcome. Interface 310 is to be connected directly to interface 210 for transmitting parallel signals in the way shown in FIG. 1. For connection between interface 110 and interface 210, they are first converted into serial interface 150 and 250, respectively, for the purpose of reducing the number of pins that carry the transmission signals. The PDA serial interface 150 and the jacket serial interface 250 are connected through connector 106 and 108 as described in FIG. 1. On the side of the PDA 100, the parallel signals 120 transmitted by the parallel interface 110 are converted into serial signals 140 of the serial interface 150 using a first parallel-serial converter 130. Similarly, on the side of the jacket 200, the parallel signals 220 of the parallel interface 210 are converted into serial signals 240 of the serial interface 250 using a second parallel-serial converter 230. The parallel-serial signal conversion in the first converter 130 and second converter 230 is bi-directional, which is determined by respective directional control signal DIR1 and DIR2. To achieve parallel-serial conversion the first converter 130 and the second converter 230 also require clock signals that determine the sampling rate. Clock signal CLK1 and CLK2 serve this function, and are kept at equal rates to maintain compliance between PDA signals and jacket signals. By introducing the first converter 130 and the second converter 230 between the parallel interface 110 and parallel interface 210, which used to connect to each other straightforwardly in the prior art, parallel signals between the PDA 100 and the jacket 200 are transmitted through serial interface 150 and serial interface 250 with reduced number of connector pins.

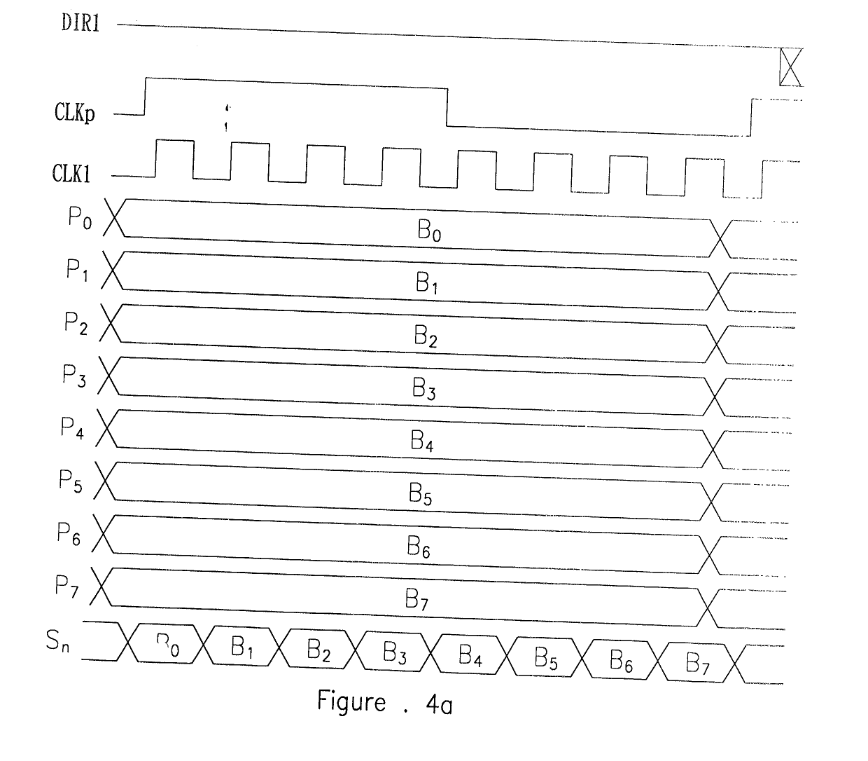

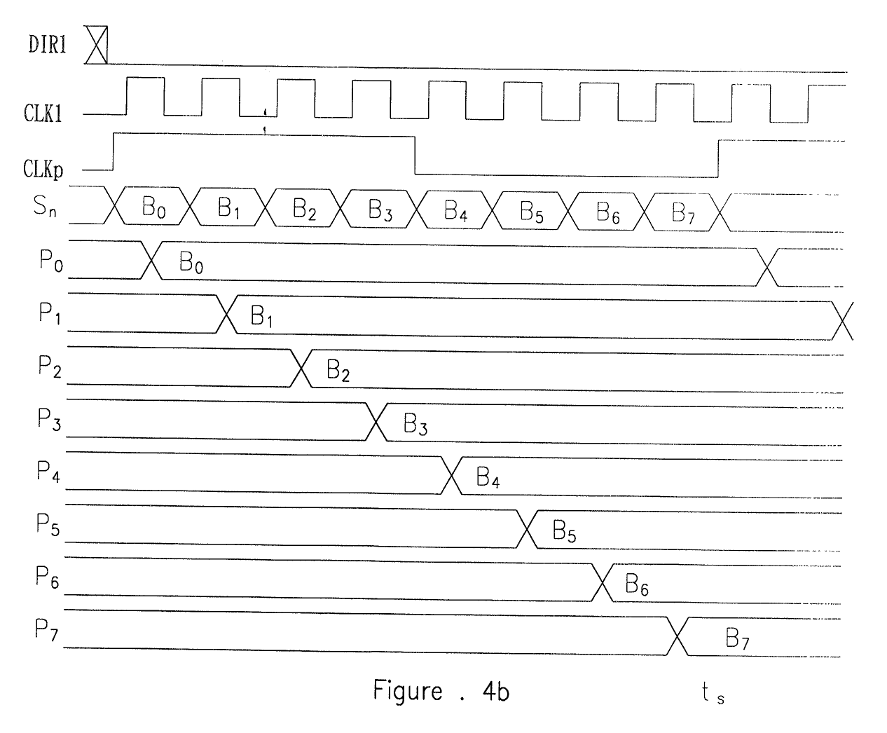

There are ways for converting parallel signals to serial signals. A method is illustrated in FIG. 4, wherein FIG. 4a illustrates the forward, parallel-to-serial, conversion and FIG. 4b illustrates the backward, serial-to-parallel, conversion.

The second converter 230 operates in the same manner as the first converter 130 described below. As understood by one skilled in the art, the forward conversion of parallel signals carried on a set of pins into serial signals carried on a set of pins of lesser number is achieved by rearranging the parallel signals in such a way that, within one clock cycle of the parallel signals, parallel signals carried on a particular number of pins are collected and sequentially combined to generate a serial signal that is to be fed into one pin of the serial interface. In FIG. 4a, DIR1 is brought high to indicate that the signal flow is from the parallel interface 110, with clock signal CLKp, to serial interface 150, with clock signal CLK1. Because the clock rate, or clock speed, of CLK1 is faster than that of CLKp, it is possible for a serial pin to read or sample, within one cycle of CLKp, a plurality of parallel signals on the basis of shorter cycles of CLK1. In the present embodiment, the clock speed of CLK1 is eight times faster than the speed of CLKp, so that in one cycle of CLKp serial pin Sn can receive signals B0 to B7 from eight parallel pins P0 to P7, respectively, thus effecting the forward signal conversion and reducing the number of pins required for signal transmission. Similarly, the backward conversion of a serial signal back to parallel signals can be obtained by reversing the operations just described in the forward conversion. In FIG. 4b, DIR1 is brought low to indicate the backward signal flow. For each cycle of CLK1, the signals B0 to B7 carried on serial pin Sn are sequentially read back to parallel pins P0 to P7, respectively. The readback operation is completed in one cycle of CLKp. The above explains the parallel-serial conversion in the first converter 130 and the second converter 230.

According to the conversion method described above, for fixed 68 pins of PCMCIA interface functioning with less than 8 MHz clock frequency under normal operating conditions, acceptable performance of the PDA 100 and the jacket 200 can be obtained when CLK1, as well as CLK2, are set to be around 50 MHz and the parallel-to-serial conversion ratio is set to be eight, with one serial signal representing eight separate parallel signals as described in FIG. 4a and FIG. 4b. Under such configuration, eight pins are sufficient on serial interface 150 and 250 for transmitting PCMCIA signals, excluding GND, RSRVD, and Vcc pins. This has been described in FIG. 3. Additional pins are required for transmitting GND and Vcc signals, which are omitted to simplify the drawing.

It should be pointed out that one is able to modify the clock rates of the clock signal CLK1 and CLK2, and the number of pins of the serial interface 150 and 250 for particular needs. As the clock signal CLK1 and CLK2 are set at a higher clock rate, the number of parallel signals that can be represented by one serial signal in one pin increases, and therefore fewer pins are required in serial interface 150 and 250 for representing parallel signals from parallel interface 110 and 210, and more space can be saved. Yet extreme high clock rate may cause electromagnetic interference among electrical circuits and is to be avoided for practical reasons. Therefore, setting CLK1 and CLK2 at a moderate high clock rate will bring the benefits of reduced size of PDA interface without causing electrical problems. As an improvement of the present embodiment, for example, the above-mentioned 50 MHz clock rate for the first converter 130 and the second converter 230 can be reduced to 25 MHz if, instead of sampling one parallel signals in one cycle of CLK1 in FIG. 4a, we allow two parallel signals to be sampled in one cycle of CLK1, one at the rising edge of the clock signal CLK1 and the other at the falling edge. In this way, the converter clock rate is reduced to half of its previous value and the parallel signals are represented by same number of serial signals, thereby greatly alleviating electromagnetic interference that might be caused due to too high a converter clock rate.

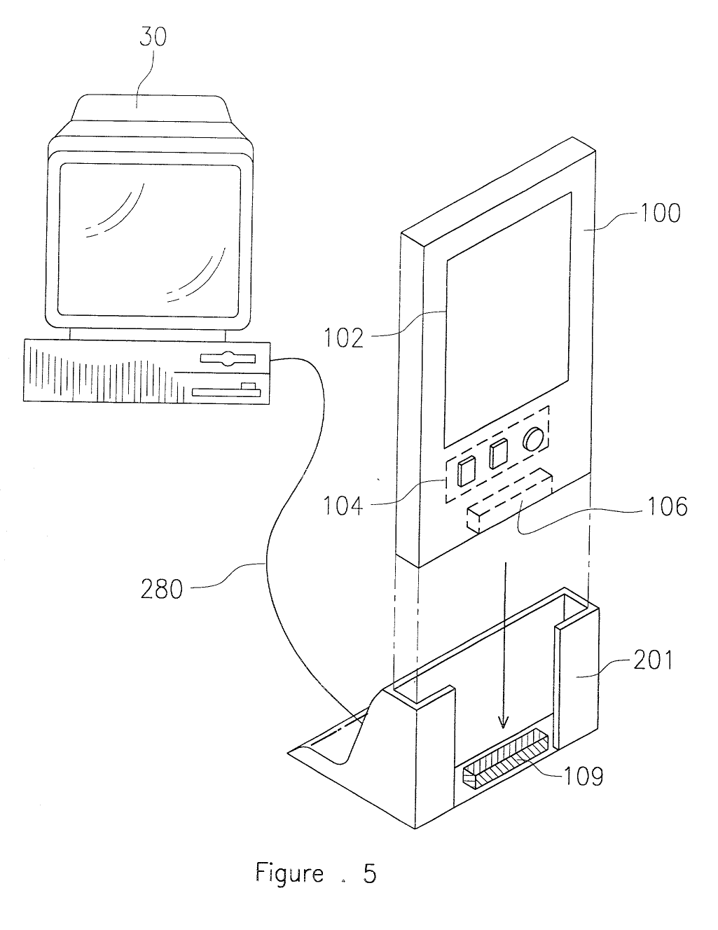

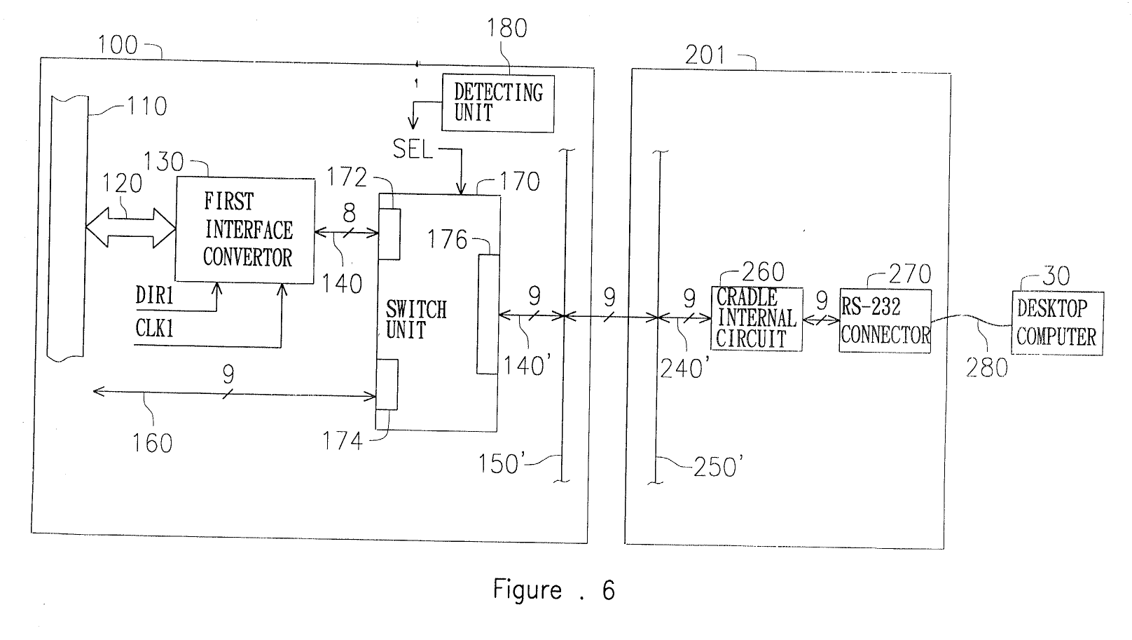

In another embodiment, the inventive PDA 100 can also connect to a desktop computer 30, as illustrated in FIG. 5, through a cradle 201 using the same connector 106 that is used for connecting to the jacket 200. By combining two separate interfaces into one, further reduction of physical size of the interface for external connection is accomplished. This is made possible by introducing a switch mechanism between the parallel signals and RS-232 signals. FIG. 6 is a schematic diagram for another embodiment of the present invention. According to the embodiment, parallel signals 120 are bidirectionally converted into serial signals 140 in the same way described above. The serial signals 140 are not to be connected to the cradle straightforwardly, but are directed to first port 172 of a switch unit 170 whose second port 174 receives RS-232 signals from internal circuitry of the PDA 100. The switch unit 170 has a third port 176 connected to a nine-pined interface 150′ that is to connect to corresponding nine-pined interface 250′ on the side of the cradle 201 for signal transfer. The switch unit 170 comprises simple logic circuits that allow the third port 176 to electrically connect to either the first port 172 or the second port 174 according to a selecting signal SEL. When the third port 176 is connected to the first port 172, the interface 150′ can be used for signal transfer between the PDA 100 and the jacket 200. In such case, although the interface 150′ includes nine pins and the serial signals 140 only needs eight pins for transmission, the problem can be resolved by defining one pin of the interface 150′ to be unassigned or reserved when the first port 172 and the third port 176 are connected. Some adjustments on the interface 250 of the jacket 200, which includes only eight pins, would also be required to make it physically connectable to the interface 150′.

On the other hand, when the third port 176 connects to the second port 174 responsive to the selecting signal SEL, RS-232 signals 160 can be transmitted through the third port 176 and the interface 150′ directly to the interface 250′ of the cradle 201. With the help of the cradle 201 connected to the desktop computer 30 using RS-232 cable 280, the PDA 100 is able to transfer data with the desktop computer 30 and perform tasks following RS-232 standard. By making the third port 176 switchable between connecting to the first port 172 for transmitting parallel signals 120 and connecting to the second port for transmitting serial signals 160, the PDA 100 is capable of information transfer with the jacket 200 and the docking cradle 201 using the same interface 150′, which is advantageous over prior art where the parallel signals and serial signals are separately transferred through separate connectors. The prior art requires at least 68 pins for PCMCIA transmission plus 9 pins for RS-232 transmission. But in the present invention, the inventive PDA 100 requires only 9 pins plus additional GND and Vcc pins for both PCMCIA transmission and RS-232 transmission. The reduction of pins is tremendous.

The selecting signal SEL can be issued from a dedicated button on the PDA 100 when depressed by the user attempting to change connection to either the jacket 200 or the cradle 201. A more convenient and user-friendly implementation is to incorporate a detecting unit 180 to the PDA 100 for automatically generating the selecting signal SEL without control of the user's hand. The detecting unit 180 detects and monitors the connection of the PDA 100 with either the jacket 200 or the cradle 201. When the PDA 100 makes connection with the jacket 200 via the interface 150′, 250, the connection event will be detected by the detecting unit 180. Subsequently the selecting signal SEL is generated and causes the switch unit 170 to have the third port 176 connect to the first port 172 so that parallel signal transfer between the PDA 100, the jacket 200, and the expansion card 300 is made possible. On the other hand, when the PDA 100 makes connection with the cradle 201 via the interface 150′, 250′, the selecting signal SEL generated by the detecting unit 180 will cause the switch unit 170 to have the third port 176 connect to the second port 174 so that serial signal transfer between the PDA 100, the cradle 201, and the desktop computer 30 can be effected. By the detecting unit 180, the PDA 180 can auto-detect which device is being connected to the interface 150′, and switch to the corresponding signal transfer mode.

There are many ways to implement the function of the detecting unit 180. For example, a light sensible device can be attached to appropriate section of the PDA 100 for determining the presence of the jacket 200. When the PDA 100 and the jacket 200 are connected, the device senses the presence of the jacket 200 and issues a signal to the switch unit 170 to have the parallel signal transfer mode switched on. But when the PDA 100 and the jacket 200 are disconnected, the absence of the jacket 200 causes no signal to be issued by the light sensible device and the parallel signal transfer mode is not effected, so that the PDA 100 can transfer serial signals with the cradle 201 as default. Another example is to assign a particular pin of the interface 150′ as the detecting unit 180. The detecting pin is characterized by that when it is the jacket 200 that is connected its voltage level is brought high, and when it is the docking cradle 201 that is connected its voltage level is brought low. When the voltage level is high, the parallel signal transfer mode is switched on, and when the voltage level is low, the serial signal transfer mode is switched on. This also gives the PDA 100 an auto-detection function.

One further advantage of the present invention is that the first interface converter 130 and the switch unit 170 can be built into a switchable interface module that can be easily and flexibly incorporated into existing PDA hardware circuitry in which the parallel signals 120 and serial signals 160 are generated. The modularization of the switch circuitry saves time and cost for PDA manufacturers, for all that needs to be done in providing a switchable interface to a PDA is to direct the parallel signals of the PDA to the converter part of the switchable module, and to direct the serial signals to the second port of the switch unit part of the module. It is also possible to combine the connector interface 150′ and the detecting unit 180 as part of the switchable interface module.

It is to be noted, as can be easily realized by one skilled in the art, that although the jacket serves as communicational bridge between expansion card and the PDA, the jacket itself can be designed to allow the PDA to perform certain added functions without having the expansion card slotted in. In other words, the jacket is itself an expansion module for certain functions just as the expansion card is. For example, the jacket 200 can have a built-in module or circuitry for RF transmission that provides the PDA 100 wireless communication capability. In such case the jacket and the expansion card are integrated into one device.

Having described the applicant's invention, it should be noted by the examiner that the description presented above is for disclosure only, not in any sense limiting the scope of the invention. Small modification or juxtaposition of functional elements or their equivalent substitution or replacement can be easily anticipated in accordance with the spirit of the invention by those skilled in the art. All these alternatives are construed as within the scope of the invention. The extent to which the scope of the present invention covers is defined in the following claims.

What is claimed is:

1. In a handheld information handling apparatus having a connector interface for swappable connection to appendant devices of two kinds, said appendant device of the first kind when connected thereto communicating with said information handling apparatus using a first transmission standard, and said appendant device of the second kind when connected thereto communicating with said information handling apparatus using a second transmission standard, a method of signal transmission between said information handling apparatus and said appendant devices, comprising the steps of:
representing a first set of signals generated according to said first transmission standard by a reduced set of signals, wherein said reduced set of signals is transmitted over said connector interface while said information handling apparatus is communicating with said appendant device of the first kind;
transmitting a second set of signals according to said second transmission standard over said connector interface while said information handling apparatus is communicating with said appendant device of the second kind.

2. The method according to claim 1, further comprising the step of:
generating a signal whereby is determined which set of signals out of said first set of signals according to said first transmission standard and said second set of signals according to said second transmission standard is made transmittable over said connector interface.

3. The method according to claim 1, further comprising the step of:
obtaining information of the connection of said connector interface to one of said appendant devices whereby is determined which set of signals out of said first set of signals according to said first transmission standard and said second set of signals according to said second transmission standard is made transmittable over said connector interface.

4. The method according to claim 1, wherein said first transmission standard is parallel and said second transmission standard is serial.

5. A handheld information handling system for performing a plurality of functions, comprising:
a display component for displaying information thereon;
a set of input components for operating the information handling system;
a circuitry for processing and transferring a first number of parallel signals generated in accordance with a first transmission standard while one of said functions is being performed, wherein said first number of parallel signals are generated at a first clock rate;
a first interface for external connection comprising a plurality of pins over which a second number of serial signals can be transmitted, wherein said second number is less than said first number;
a first parallel-serial converter coupling said circuitry and said first interface and thereby allowing said first number of parallel signals transferred by said circuitry and said second number of serial signals transmitted over said first interface to be mutually convertible.

6. The information handling system according to claim 5, wherein said first parallel-serial converter functions at a second clock rate, said second clock rate being a multiple of said first clock rate.

7. The information handling system according to claim 6, wherein said second clock rate is four times faster than said first clock rate.

8. The information handling system according to claim 5, further comprising a switch unit having a first port coupled to said first parallel-serial converter over which said second number of serial signals is transmitted, a second port coupled to said circuitry over which a third number of serial signals generated in accordance with a second transmission standard is transmitted, and a third port coupled to said first interface over which said second number of serial signals and said third number of serial signals are switchably transmitted.

9. The information handling system according to claim 5, further comprising a first appendant device removably connected to said first interface, comprising:
a second interface comprising a plurality of pins removably connectable to said first interface over which said second number of serial signals can be transmitted;
a second parallel-serial converter coupling said second interface and allowing said first number of parallel signals and said second number of serial signals transmitted over said second interface to be mutually convertible, wherein said second parallel-serial converter functions substantially at said second clock rate.

10. The information handling system according to claim 9, wherein said first appendant device further comprises a functional module coupled to said second parallel-serial converter between which said first number of parallel signals generated while one of said functions is being performed are exchanged.

11. The information handling system according to claim 10, wherein said functional module is in the form of an expansion module removably connected into said appendant device.

12. An information handling system comprising:
a handheld device operable independently and having a first connector for external connection, wherein said handheld device functions in accordance with a first protocol and a second protocol;
a first appendant device for said handheld device having a second connector for connecting to said first connector, wherein said first appendant device cooperates with said handheld device according to said first protocol inasmuch as said second connector is connected to said first connector;
a second appendant device for said handheld device having a third connector for connecting to said first connector, wherein said second appendant device cooperates with said handheld device according to said second protocol inasmuch as said third connector is connected to said first connector;
wherein:
said first connector has connector pins whose number is less than the number specified in said first protocol for successful signal transmission between said handheld device and said first appendant device.

13. The information handling system according to claim 12, further comprising an expansion module for performing a function cooperatively with said handheld device, wherein said expansion module performs said function according to said first protocol inasmuch as said expansion module is connected to said first appendant device and said second connector is connected to said first connector.

14. The information handling system according to claim 12, further comprising a computer for performing a function cooperatively with said handheld device, wherein said computer performs said function according to said second protocol inasmuch as said computer is connected to said second appendant device and said third connector is connected to said first connector.

15. The information handling system according to claim 12, wherein said first protocol is PCMCIA.

16. The information handling system according to claim 12, wherein said first protocol is COMPACT FLASH.

17. The information handling system according to claim 12, wherein said second protocol is RS-232.

18. The information handling system according to claim 12, wherein said handheld device further comprising circuitry for determining according to which of said first protocol and said second protocol that signals are transmitted over said first connector.

19. The information handling system according to claim 12, further comprising an apparatus for obtaining information about whether one of said first appendant device and said second appendant device is connected to said handheld device.

20. The information handling system according to claim 19, wherein said apparatus is a connector pin of said first connector.
